(19) United States
(12) Patent Application Publication
(10) Pub. No.: US 2025/0107402 A1
(43) Pub. Date: Mar. 27, 2025

(54) DISPLAY DEVICE

(71) Applicant: LG Display Co., Ltd., Seoul (KR)

(72) Inventor: Chikyung SUNG, Paju-si (KR)

(21) Appl. No.: 18/816,908

(22) Filed: Aug. 27, 2024

(30) Foreign Application Priority Data
Sep. 26, 2023 (KR) 10-2023-0129122

(51) Int. Cl. H10K 59/80

(52) U.S. Cl. CPC H10K 59/873

(57) ABSTRACT

A display device includes a display panel including a display area and a non-display area with a bent area, a cover member disposed on top of the display panel, a back plate disposed on a rear surface of the display panel, a coating layer disposed on the bent area of the non-display area, and a protective film disposed to overlap at least a portion of the cover member on the bent area and cover the coating layer and at least a portion of a side surface of an edge of the back plate.

### CROSS-REFERENCE TO RELATED APPLICATION

This application claims priority from Korean Patent Application No. 10-2023-0129122 filed on Sep. 26, 2023 in the Korean Intellectual Property Office, and all the benefits accruing therefrom under 35 U.S.C. 119, the contents of which in its entirety are herein incorporated by reference.

### BACKGROUND

### Technical Field

The present disclosure relates to a display device, and more specifically, for example, without limitation, to a display device that may implement a narrow bezel of the display device and reinforce rigidity to improve a reliability of the display device.

### Description of Related Art

Various schemes and forms are used for a display device that displays an image in a TV, a monitor, a smartphone, a tablet PC, and a laptop.

The display devices include a plurality of light-emitting elements or liquid crystals to implement the image, and a display panel with a driving transistor to individually control an operation of each light-emitting element or liquid crystal, and allow the plurality of light-emitting elements or liquid crystals to display an image to be displayed.

An organic light-emitting display device with self light-emitting elements may be implemented thinner than a display device with a built-in light source (e.g., LCD), and may be bent or implement various designs because a separate light source is not required.

As the information age is entered, a field of the display device that visually displays an electrical information signal is developing rapidly, and research to develop performances such as thinning, lighting, and lower power consumption for various display devices is continuing.

### BRIEF SUMMARY

Embodiments of the present disclosure is to provide a display device that enables a narrow bezel by applying different types of protective films depending on bezel partial areas.

Embodiments of the present disclosure is to provide a display device that prevents metal corrosion, moisture penetration, or the like to improve reliability by placing different types of protective films on outer sides of a display panel for bezel partial areas.

Embodiments of the present disclosure is to provide a display device that may approach realization of an eco-friendly display device using a material that does not have a harmful effect on a human body as a protective film disposed on at outer side of a display panel.

Purposes according to the present disclosure are not limited to the above-mentioned purpose. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using means shown in the disclosure.

A display device according to one aspect of the present disclosure includes a display panel including a display area and a non-display area with a bent area, a cover member disposed on top of the display panel, a back plate disposed on a rear surface of the display panel, a coating layer disposed on the bent area of the non-display area, and a protective film disposed to overlap at least a portion of the cover member on the bent area and cover the coating layer and at least a portion of a side surface of an edge of the back plate.

The protective film may be disposed on one partial bezel area of the display panel where the bent area is disposed, and a resin layer may be further disposed on remaining three partial bezel areas of the display panel where the bent area is not disposed.

A thickness of the protective film may be smaller than a thickness of the resin layer.

The protective film may cover a side surface of an edge of the first back plate and a side surface of an edge of the first adhesive layer adjacent to the bent area, and a side surface of an edge of the second back plate and a side surface of an edge of the second adhesive layer adjacent to the bent area.

The protective film may be disposed to overlap a side surface of an edge of the coating layer and a top surface of the coating layer.

The display device may further include an adhesive member disposed between the display panel and the back plate, the adhesive member may include a cushion layer disposed between the first back plate and the second back plate, and the protective film may be disposed to cover a side surface of an edge of the cushion layer on the non-display area.

The cover member and the coating layer may be disposed to be spaced apart from each other in a bezel area having the bent area, and the protective film may be disposed to overlap at least a portion of a rear surface of the cover member and overlap an entirety of a top surface of the coating layer in a separation space where the rear surface of the cover member and the top surface of the coating layer are spaced apart from each other.

The display device may further include an optical adhesive member disposed between the cover member and the display panel within the separation space, and an optical plate disposed between the optical adhesive member and the display panel and more protruding toward the bent area than the optical adhesive member, and the protective film may be disposed to cover a side surface of the optical adhesive member perpendicular to a top surface of the display panel, a side surface of the optical plate perpendicular to the top surface of the display panel, and a protruding top surface of the optical plate in the non-display area adjacent to the bent area.

The protective film may be a film containing an organic material but may be composed of a material not containing isobornyl acrylate (IBOA).

The protective film may contain a parylene-based organic material.

The display device according to the present disclosure may improve the reliability of the display device by applying the protective film to the bezel area to prevent the metal corrosion and block the gas, the moisture, and the like.

The display device according to the present disclosure may achieve the narrow bezel as the display device may be prevented from being damaged by the external impact or the like, and at the same time, the bezel area may be reduced by applying the protective films made of the different materials and having the different thicknesses to the partial bezel areas on the four sides.

The display device according to the present disclosure may use the parlyne-based material as the protective film, which enables the constant thickness in the bezel area and minimizes the thermal deformation.

The display device according to the present disclosure may realize the eco-friendly product by preventing the harmful effect on the human body by composing the protective film with the material that does not contain isobornyl acrylate (IBOA).

Effects of the present disclosure are not limited to the effects mentioned above, and other effects not mentioned will be clearly understood by those skilled in the art from the description below. In addition to the above effects, specific effects of the present disclosure are described together while describing specific details for carrying out the present disclosure.

### BRIEF DESCRIPTION OF THE SEVERAL VIEWS OF THE DRAWINGS

FIG. 1 is a plan view of a display device according to an embodiment.

FIG. 2 is a rear perspective view of the display device in FIG. 1.

FIG. 3 is a circuit diagram of a sub-pixel according to an embodiment.

FIG. 4 is an embodiment of a cross-sectional view taken along a line I-I′ in FIG. 1.

FIG. 5 is an enlarged view of a portion A in FIG. 4.

FIG. 6 is an embodiment of a cross-sectional view along a line II-II′ in FIG. 1.

### DETAILED DESCRIPTION

Advantages and features of the present disclosure, and a method of achieving the advantages and features will become apparent with reference to embodiments described later in detail together with the accompanying drawings. However, the present disclosure is not limited to the embodiments as disclosed under, but may be implemented in various different forms. Thus, these embodiments are set forth only to make the present disclosure complete, and to completely inform the scope of the present disclosure to those of ordinary skill in the technical field to which the present disclosure belongs, and the claims are not defined by the present disclosure.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as may be included within the spirit and scope of the claims. Accordingly, the claims are not limited by the disclosure.

A shape, a size, a ratio, an angle, a number, etc., disclosed in the drawings for illustrating embodiments of the present disclosure are illustrative, and embodiments of the present disclosure are not limited thereto.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “comprising”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items. Expression such as “at least one of” when preceding a list of elements may modify the entire list of elements and may not modify the individual elements of the list. In interpretation of numerical values, an error or tolerance therein may occur even when there is no explicit description thereof.

In addition, it will also be understood that when a first element or layer is referred to as being present “on” a second element or layer, the first element may be disposed directly on the second element or may be disposed indirectly on the second element with a third element or layer being disposed between the first and second elements or layers. It will be understood that when an element or layer is referred to as being “connected to”, or “connected to” another element or layer, it may be directly on, connected to, or connected to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

Further, as used herein, when a layer, film, region, plate, or the like is disposed “on” or “on a top” of another layer, film, region, plate, or the like, the former may directly contact the latter or still another layer, film, region, plate, or the like may be disposed between the former and the latter. As used herein, when a layer, film, region, plate, or the like is directly disposed “on” or “on a top” of another layer, film, region, plate, or the like, the former directly contacts the latter and still another layer, film, region, plate, or the like is not disposed between the former and the latter. Further, as used herein, when a layer, film, region, plate, or the like is disposed “below” or “under” another layer, film, region, plate, or the like, the former may directly contact the latter or still another layer, film, region, plate, or the like may be disposed between the former and the latter. As used herein, when a layer, film, region, plate, or the like is directly disposed “below” or “under” another layer, film, region, plate, or the like, the former directly contacts the latter and still another layer, film, region, plate, or the like is not disposed between the former and the latter.

In descriptions of temporal relationships, for example, temporal precedent relationships between two events such as “after”, “subsequent to”, “before”, etc., another event may occur therebetween unless “directly after”, “directly subsequent” or “directly before” is not indicated.

When a certain embodiment may be implemented differently, a function or an operation specified in a specific block may occur in a different order from an order specified in a flowchart. For example, two blocks in succession may be actually performed substantially concurrently, or the two blocks may be performed in a reverse order depending on a function or operation involved.

It will be understood that, although the terms “first”, “second”, “third”, and so on may be used herein to describe various elements, components, regions, layers and/or periods, these elements, components, regions, layers and/or periods should not be limited by these terms. These terms are used to distinguish one element, component, region, layer or section from another element, component, region, layer or period. Thus, a first element, component, region, layer or section as described under could be termed a second element, component, region, layer or period, without departing from the spirit and scope of the present disclosure.

A term “device” used herein may refer to a display device including a display panel and a driver for driving the display panel. Examples of the display device may include a light emitting element, and the like. In addition, examples of the device may include a notebook computer, a television, a computer monitor, an automotive device, a wearable device, and an automotive equipment device, and a set electronic device (or apparatus) or a set device (or apparatus), for example, a mobile electronic device such as a smartphone or an electronic pad, which are complete products or final products respectively including light emitting element and the like, but embodiments of the present disclosure are not limited thereto.

The features of the various embodiments of the present disclosure may be partially or entirely combined with each other, and may be technically associated with each other or operate with each other. The embodiments may be implemented independently of each other and may be implemented together in an association relationship.

In interpreting a numerical value, the value is interpreted as including an error range unless there is no separate explicit description thereof.

It will be understood that when an element or layer is referred to as being “connected to”, or “connected to” another element or layer, it may be directly on, connected to, or connected to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “embodiments,” “examples,” “aspects, and the like should not be construed such that any aspect or design as described is superior to or advantageous over other aspects or designs.

Further, the term ‘or’ means ‘inclusive or’ rather than ‘exclusive or’. That is, unless otherwise stated or clear from the context, the expression that ‘x uses a or b’ means any one of natural inclusive permutations.

The terms used in the description below have been selected as being general and universal in the related technical field. However, there may be other terms than the terms depending on the development and/or change of technology, convention, preference of technicians, etc. Therefore, the terms used in the description below should not be understood as limiting technical ideas, but should be understood as examples of the terms for illustrating embodiments.

Further, in a specific case, a term may be arbitrarily selected by the applicant, and in this case, the detailed meaning thereof will be described in a corresponding description period. Therefore, the terms used in the description below should be understood based on not simply the name of the terms, but the meaning of the terms and the contents throughout the Detailed Descriptions.

In description of flow of a signal, for example, when a signal is delivered from a node A to a node B, this may include a case where the signal is transferred from the node A to the node B via another node unless a phrase ‘immediately transferred’ or ‘directly transferred’ is used.

Hereinafter, a display device according to some embodiments will be described.

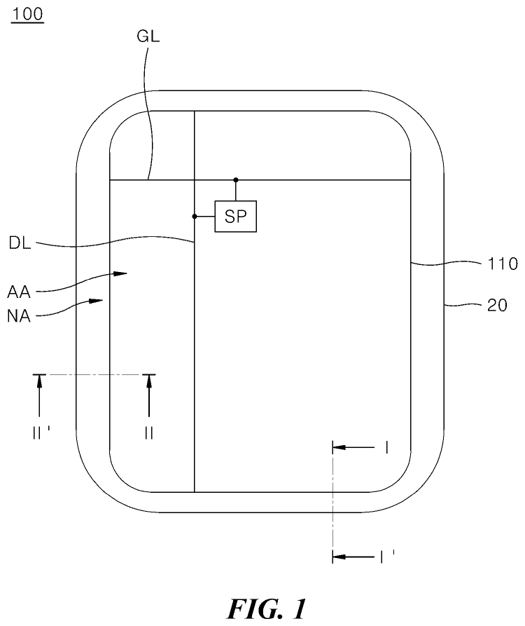

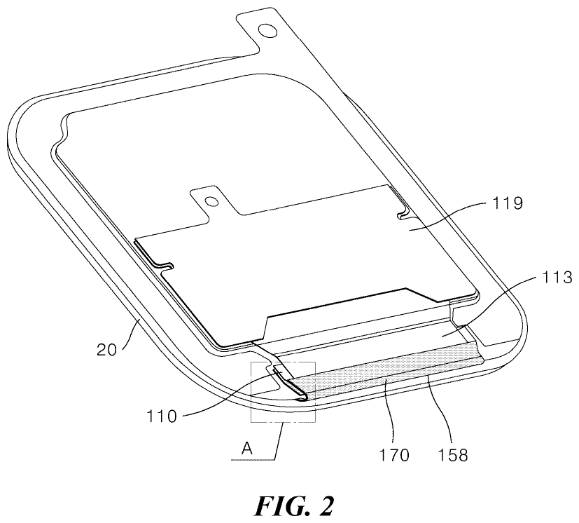

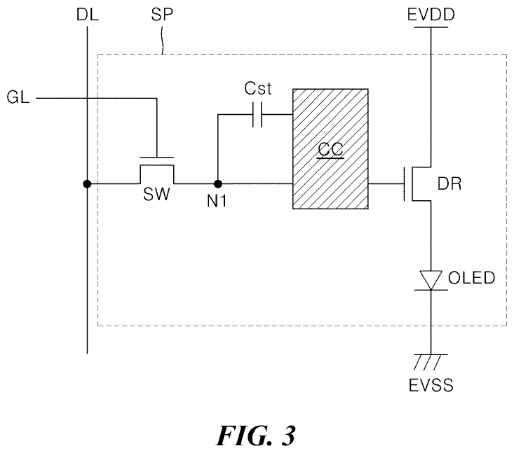

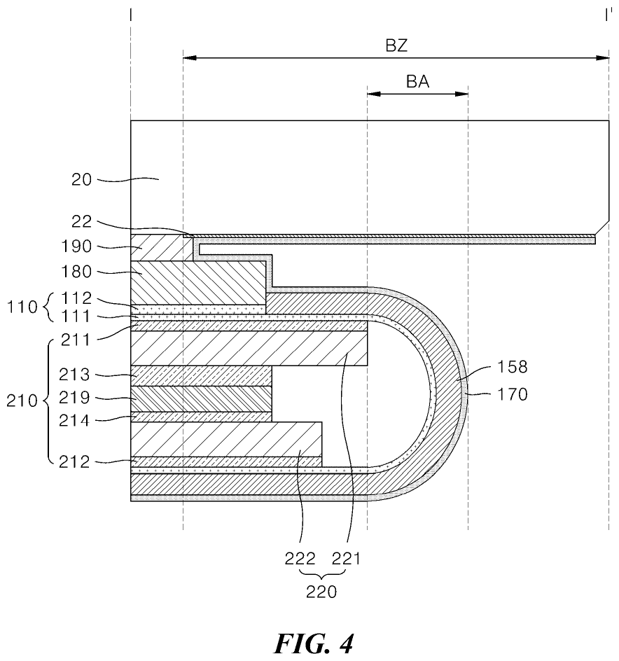

Hereinafter, a display device of the present disclosure will be described via the attached drawings and embodiments. FIG. 1 is a plan view of a display device according to an embodiment, FIG. 2 is a rear perspective view of the display device in FIG. 1, FIG. 3 is a circuit diagram of a pixel according to an embodiment, and FIG. 4 is an embodiment of a cross-sectional view taken along a line I-I′ in FIG. 1.

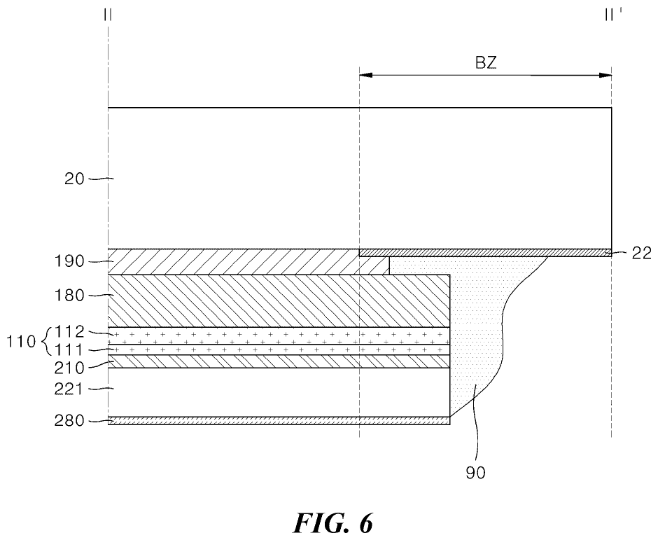

Referring to FIGS. 1 to 4, a display device 100 according to an example of the present disclosure may include a display panel 110, a cover member 20 disposed on top of the display panel 110, and a back plate 220 disposed under the display panel 110, and may include a coating layer 158 disposed on a bent area BA of the display panel 110 and a protective film 170 disposed on one partial bezel area BZ at a side of the display panel 110. The display device 100 may further include a resin layer 90 (see FIG. 6) in the remaining partial bezel areas BZ at sides of the display panel 110 where the protective film 170 is not disposed.

The display panel 110 may include a display area AA where an image is displayed and a non-display area NA, which is an area other than the display area AA. The non-display area NA is configured to be in the vicinity of the display area AA, partially or fully surround the display area AA

The non-display area NA may be formed in an edge area surrounding the display area AA. At least one driver to drive a pixel may be disposed in the non-display area NA. The driver may be a gate-in-panel (GIP) or a driving integrated circuit (D-IC). The display panel 110 may include the bent area BA (see FIG. 4), which is bent at one side of a front surface of the display panel 110 in the non-display area NA. One side of the front surface of the non-display area NA of the display panel 110 is bent by the bent area BA, so that a rear surface of the display panel 110 and a rear surface of the non-display area NA of the display panel 110 may face each other.

The non-display area NA may be an area that has the bent area BA at one side of the display panel 110 and overlaps bezel area BZ of the display device 100. The bezel area BZ may be disposed at four sides of the display panel 110. The bezel area BZ may include the partial bezel area at one side that overlaps the bent area BA of display panel 110 and the partial bezel areas at the remaining three sides that do not overlap the bent area BA of the display panel 110 or overlap the non-display area NA where the bent area BA is not defined. The non-display area NA adjacent to the bent area BA may be connected to a driving film 113.

The driving film 113 is disposed on the rear surface of the display panel 110. The driving film 113 may have multiple wirings (not shown) for driving the display panel 110 and may have at least one driver circuit chip (not shown). Terminals provided on predetermined sides of the driving film 113 may be connected to a printed circuit board (not shown) or a flexible circuit board (not shown) by a film attaching process.

A shielding member 119 at least covering a portion of the driving film 113 may be further disposed on the rear surface of the display panel 110.

The shielding member 119 may be disposed to cover the printed circuit board (not shown) connected to the driving film 113, protect the driver circuit chip (not shown) disposed between the driving film 113 and the rear surface of the display panel 110, and perform an electro-static discharge (ESD) function to components adjacent thereto. for example, driver circuit chip may include a data driver circuit and a gate driver circuit, and may further include a controller for controlling the data driver circuit and the gate drive circuit.

Multiple sub-pixels SP may be arranged in the display area AA of the display panel 110, and the image may be displayed using the multiple sub-pixels SP.

Referring to FIG. 3, at least one sub-pixel SP among the multiple pixels may include a switching transistor SW, a driving transistor DR, a capacitor Cst, a compensation circuit CC, and an organic light-emitting diode OLED. However, the present disclosure is not limited thereto. For example, a number of transistors TFTs in the pixel circuit of the present disclosure may be two or more, and a number of capacitor may be one or more.

Active layers or semiconductor layer of the transistors TFTs may be formed of a semiconductor material, such as an oxide semiconductor, amorphous semiconductor, or polycrystalline semiconductor, but is not limited thereto.

The oxide semiconductor material may have an excellent effect of preventing a leakage current and relatively inexpensive manufacturing cost. The oxide semiconductor may be made of a metal oxide such as zinc (Zn), indium (In), gallium (Ga), tin (Sn), and titanium (Ti) or a combination of a metal such as zinc (Zn), indium (In), gallium (Ga), tin (Sn), or titanium (Ti) and its oxide. Specifically, the oxide semiconductor may include zinc oxide (ZnO), zinc-tin oxide (ZTO), zinc-indium oxide (ZIO), indium oxide (InO), titanium oxide (TiO), indium-gallium-zinc oxide (IGZO), indium-zinc-tin oxide (IZTO), indium zinc oxide (IZO), indium gallium tin oxide (IGTO), and indium gallium oxide (IGO), but is not limited thereto.

The polycrystalline semiconductor material has a fast movement speed of carriers such as electrons and holes and thus has high mobility, and has low energy power consumption and superior reliability. The polycrystalline semiconductor may be made of polycrystalline silicon (poly-Si), but is not limited thereto.

The amorphous semiconductor material may be made of amorphous silicon (a-Si), but is not limited thereto.

Referring to FIG. 3, a first electrode (e.g., a drain electrode) of the switching transistor SW is electrically connected to a data line DL, and a second electrode (e.g., a source electrode) is electrically connected to a first node N1. A gate electrode of the switching transistor SW is electrically connected to a gate line GL. The switching transistor SW transmits a data signal supplied via the data line DL to the first node N1 in response to a scan signal supplied via the gate line GL.

The capacitor Cst is electrically connected to the first node N1 and charges a voltage applied to the first node N1.

A first electrode (e.g., a drain electrode) of the driving transistor DR is applied with a high potential driving voltage EVDD, and a second electrode (e.g., a source electrode) is electrically connected to a first electrode (e.g., an anode electrode) of the organic light-emitting diode OLED. The driving transistor DR may control an amount of driving current flowing through the organic light-emitting diode OLED in response to a voltage applied to a gate electrode thereof.

A semiconductor layer of the switching transistor SW and/or the driving transistor DR may contain silicon such as amorphous silicon (a-Si), polycrystalline silicon (poly-Si), or low-temperature polycrystalline silicon (poly-Si), or oxide such as indium-gallium-zinc-oxide (IGZO), but the present disclosure may not be limited thereto.

The organic light-emitting diode OLED outputs light corresponding to the driving current. The organic light-emitting diode OLED may output light with a color corresponding to one of red, green, blue, and white.

The organic light-emitting diode OLED may include the anode electrode, a light-emitting layer disposed on the anode electrode, and a cathode electrode that supplies a common voltage. The light-emitting layers may be implemented to emit light of the same color for each pixel, such as white light, or may be implemented to emit light of different colors, such as red, green, or blue light, for respective sub-pixels SP. The sub pixel SP is a minimum unit which configures the display area and n sub pixels SP form one pixel. Each of the plurality of sub pixels SP may emit light having different wavelengths from each other. The plurality of sub pixels may include first to third sub pixels which emit different color light from each other. For example, the plurality of subpixels SP may include red subpixels SP, green subpixels SP, and blue subpixels SP. According to the exemplary embodiment, at least some of the plurality of pixels may further include white subpixels SP. The plurality of subpixels SP may be variously modified in colors and configurations, as necessary. However, the present disclosure is not limited thereto.

For example, the plurality of sub pixels SP may include red, green, and blue sub-pixels, in which the red, green, and blue sub-pixels may be disposed in a repeated manner. Alternatively, the plurality of sub pixels SP may include red, green, blue, and white sub-pixels, in which the red, green, blue, and white sub-pixels may be disposed in a repeated manner, or the red, green, blue, and white sub-pixels may be disposed in a quad type. For example, the red sub pixel, the blue sub pixel, and the green sub pixel may be sequentially disposed along a row direction, or the red sub pixel, the blue sub pixel, the green sub pixel and the white sub pixel may be sequentially disposed along the row direction. However, in the embodiment of the present disclosure, the color type, disposition type, and disposition order of the sub-pixels are not limiting, and may be configured in various forms according to light-emitting characteristics, device lifespans, and device specifications.

Meanwhile, the sub-pixels may have different light-emitting areas according to light-emitting characteristics. For example, a sub-pixel that emits light of a color different from that of a blue sub-pixel may have a different light-emitting area from that of the blue sub-pixel. For example, the red sub-pixel, the blue sub-pixel, and the green sub-pixel, or the red sub-pixel, the blue sub-pixel, the white sub-pixel, and the green sub-pixel may each has a different light-emitting area.

The compensation circuit CC may be disposed in the sub-pixel SP to compensate for a threshold voltage or the like of the driving transistor DR. The compensation circuit CC may be composed of one or more transistors and disposed between the gate of the driving transistor DR and the capacitor Cst. The compensation circuit CC may include one or more transistors and a capacitor, and may be constructed in various ways depending on a compensation method. A pixel including the compensation circuit CC may have various structures such as 3T1C, 4T2C, 5T2C, 6T1C, 6T2C, 7T1C, 7T2C, and the like.

As shown in FIG. 4, the display panel 110 may include a display substrate 111 including a pixel array with the multiple sub-pixels SP, and an encapsulation portion 112.

The display substrate 111 on which the sub-pixels SP are arranged may be made of a flexible plastic material and have flexible characteristics. For example, the display substrate 111 may be formed to contain polyimide and may contain a thin glass material with flexibility. Furthermore, in some exemplary embodiments, the display substrate 111 may be made of a flexible polymer film. For example, the flexible polymer film may be made of any one of polyimide (PI), polyethylene terephthalate (PET), acrylonitrile-butadiene-styrene copolymer (ABS), polymethyl methacrylate (PMMA), polyethylene naphthalate (PEN), polycarbonate (PC), polyethersulfone (PES), polyarylate (PAR), polysulfone (PSF), cyclic olefin copolymer (COC), triacetylcellulose (TAC), polyvinyl alcohol (PVA), and polystyrene (PS), and the present disclosure is not limited thereto.

The pixel array constituting the multiple sub-pixels SP may be disposed on the display substrate 111. A portion where the pixel array constituting the multiple sub-pixels SP is disposed may be the display area AA, as shown in FIG. 1. Therefore, an area corresponding to the pixel array where the multiple sub-pixels SP are arranged may become the display area AA, and an area other than the display area AA may become the non-display area NA.

The encapsulation portion 112 may be disposed on the display substrate 111 to cover the multiple sub-pixels SP. The encapsulation portion 112 may prevent oxygen, moisture, or foreign substances from penetrating into the multiple sub-pixels SP. The encapsulation portion 112 may be formed in a multi-layer structure in which an organic material layer and an inorganic material layer are alternately stacked, but the present disclosure may not be limited thereto. The encapsulation portion 112 may have a multi-insulating film structure in which the organic film and the inorganic film are alternately stacked. The inorganic film blocks penetration of oxygen, moisture, or foreign. The organic film planarizes the surface of the inorganic film. When the organic film and the inorganic film are stacked in several layers, a movement path of oxygen, moisture, or foreign is longer than that of a single layer, so that penetration of oxygen, moisture, or foreign affecting the light emitting device layer 14 may be effectively blocked.

The encapsulation portion 112 may include a first encapsulation layer, a second encapsulation layer, and a third encapsulation layer. The first encapsulation layer to the third encapsulation layer may be sequentially stacked on the display substrate 111, the first encapsulation layer and the third encapsulation layer may be formed of an inorganic film layer including an inorganic material, and the second encapsulation layer may be formed of an organic film layer including an organic material.

The first encapsulation layer may be formed at the lowermost end of the encapsulation portion 112, for example, may be in contact with the upper surface of the display substrate 111. The first encapsulation layer may be formed of a material such as silicon nitride SiNx, silicon oxide SiOx, silicon oxynitride SiON, or aluminum oxide Al2O3.

The second encapsulation layer may be formed on the first encapsulation layer. The second encapsulation layer may be formed of a material such as acrylic resin, epoxy resin, polyimide, polyethylene PE, or silicon oxycarbon SiOC.

The third encapsulation layer may be formed on the second encapsulation layer. The third encapsulation layer may be formed of the same material as the first encapsulation layer, but not limited thereto, the third encapsulation layer may be formed of different material from the first encapsulation layer.

Meanwhile, the encapsulation portion 112 are not limited to three layers, for example, n layers alternately stacked between inorganic encapsulation layer and organic encapsulation layer (where n is an integer greater than 3) may be included.

One area of the non-display area NA of the display panel 110 includes the bent area BA. The bent area BA is bent 180° in a direction of the rear surface of the display panel 110 in the non-display area NA, so that the display panel 110 may have a “C” shape, have a curvature, and be bent downwards. In this regard, the bent area BA may be defined including a lower side of the display panel 110.

The coating layer 158 is disposed in the bent area BA.

The coating layer 158 may be disposed in the non-display area NA of the display panel 110 to cover the side surface of the encapsulation portion 112. The coating layer 158 may overlap at least a portion of a top surface of the encapsulation portion 112. The coating layer 158 may be disposed extending from the bent area BA of the display panel 110 to the non-display area NA of the display panel 110 toward the encapsulation portion 112 and the non-display area NA of the display panel 110 toward the driving film 113.

One side of the coating layer 158 may partially overlap a first back plate 221, and may be bent together with the bent area BA of the display panel 110, so that the other side of the coating layer 158 may partially overlap a second back plate 222.

Because the coating layer 158 may cover various signal wirings disposed between the encapsulation portion 112 and the driving film 113 of the display panel 110, the coating layer 158 may protect the signal wiring from an external impact and prevent the moisture from penetrating into the signal wiring.

In the bent area BA, to increase the flexibility of the display panel 110, other components except the display substrate 111 and the signal wirings may be removed and thus rigidity may be reduced, and the coating layer 158 may supplement the rigidity of the bent area BA with other components removed.

The coating layer 158 may be referred to as a micro coating layer (MLC).

The cover member 20 may be disposed on top of the display panel 110 to cover the front surface of the display panel 110 and may protect the display panel 110 from the external impact. The cover member 20 may be made of a transparent material so as to overlap an image display area or the display area AA. For example, the cover member 20 may be made of a transparent plastic material or a transparent glass material that may transmit the image, but the present disclosure may not be limited thereto.

An edge of the cover member 20 may have a cut portion facing in a direction of the display panel 110. The cover member 20 may be disposed to cover a side surface area of the display panel 110 disposed on a rear surface thereof, and may protect the display panel 110 from the external impact not only on the front surface of the display device 100 but also on the side surface.

The display area AA and the non-display area NA may be equally applied to the cover member 20. An area through which the image is transmitted in the cover member 20 may be the display area AA. In the cover member 20, an area surrounding the display area AA and not transmitting the image may be the bezel area BZ, including the non-display area NA.

The display device 100 may further include a light-blocking pattern 22 disposed beneath the cover member 20. The light-blocking pattern 22 may be disposed in a border area of the cover member 20. The border area may be the bezel area BZ including the non-display area NA. The light-blocking pattern 22 may be disposed around four sides of the cover member 20.

The light-blocking pattern 22 may block various circuits and wirings and various structures disposed in the non-display area NA of the display panel 110 from being viewed by a user. The light-blocking pattern 22 may be made of a material that may absorb light. For example, the light-blocking pattern 22 may be formed of a black matrix or formed via a method of printing black ink, but the present disclosure may not be limited thereto.

The display device 100 may further include an optical plate 180 disposed between the display panel 110 and the cover member 20 and an optical adhesive member 190 disposed between the optical plate 180 and the cover member 20.

The light-blocking pattern 22 may be disposed to overlap at least a portion of each of the optical plate 180 and the display panel 110. The light-blocking pattern 22 is disposed to overlap at least a portion of the back plate 220 disposed under the display panel 110.

The cover member 20 may be attached to the display panel 110 or structures disposed between the display panel 110 and the cover member 20 via the optical adhesive member 190. In an outer area of the display panel 110 where the optical adhesive member 190 is not disposed, the protective film 170 may be disposed as shown in FIG. 4 or the resin layer 90 may be disposed as shown in FIG. 6. In this regard, the cover member 20 may be adhered to and fixed to the display panel 110 via the protective film 170 or/and the resin layer 90 of the bezel area BZ.

The optical plate 180 may be attached onto the display panel 110 and may improve outdoor visibility and contrast ratio for the image displayed on the display panel 110 by preventing reflection of external light. The optical plate 180 may be disposed on the display area AA, but the present disclosure may not be limited thereto. The optical plate 180 may be a polarizing plate composed of a polarizer and a protective film that protects the same, and may be formed via a scheme of coating a polarizing material for the flexibility.

The optical adhesive member 190 may serve to attach the display panel 110 to the cover member 20. Because the optical adhesive member 190 may overlap the display area AA, a material that may transmit the image of the display panel 110 may be used. For example, the optical adhesive member 190 may be made of or contain a material such as an optical clear adhesive (OCA), an optical clear resin (OCR), or a pressure sensitive adhesive (PSA), but the present disclosure may not be limited thereto.

The display device 100 includes the back plate 220 disposed under the display panel 110. The back plate 220 is disposed on the rear surface of the display panel 110 such that a lower side of the display panel 110 remains a flat surface or a flat state and the display substrate 111 is supported. The back plate 220 may be attached to the display panel 110 or the structure of the rear surface of the display panel 110 via an adhesive member 210. The back plate 220 may be disposed to protrude more than edges of the optical plate 180 and the optical adhesive member 190 toward the bent area BA.

The back plate 220 may include a first back plate 221 that supports the display area AA of the display panel 110 and is disposed to overlap the display area AA, and a second back plate 222 that supports and is disposed to overlap the non-display area NA of the display panel 110.

The first back plate 221 and the second back plate 222 are disposed to be spaced apart or separated from each other by a predetermined spacing to ensure flexibility of a curved surface in the bent area BA of the display panel 110. The second back plate 222 supports the bent display panel 110 and allows the lower portion or one end of the display panel 110 to remain flat.

The first back plate 221 may be disposed to protrude more than the second back plate 222 toward the bent area BA.

The first back plate 221 and the second back plate 222 may be made of the same material and have the same thickness, but the present disclosure is not limited thereto. For example, the first back plate 221 and the second back plate 222 may be made of different materials and/or have different thickness.

The back plate 220 may not be formed in the bent area BA where the display panel 110 is bent, or may be disposed to overlap a portion of a start portion or an end portion of the bent area BA.

The back plate 220 may be formed to have certain strength and thickness to complement the rigidity of the display substrate 111. The back plate 220 may be made of a rigid plastic thin film. For example, the back plate 220 may be made of polyethylene terephthalate (PET), polyimide (PI), polyethylene naphthalate (PEN), and the like, but the present disclosure may not be limited thereto.

The back plate 220 may be attached and fixed to the display panel 110 or may be coupled to the display panel 110 or the structures of the rear surface of the display panel 110 via the adhesive member 210.

The adhesive member 210 may include a first adhesive layer 211 disposed between the display panel 110 and the first back plate 221, a second adhesive layer 212 disposed between the display panel 110 and the second back plate 222, a third adhesive layer 213 and a fourth adhesive layer 214 disposed between the first back plate 221 and the second back plate 222, and a cushion layer 219 disposed between the third adhesive layer 213 and the fourth adhesive layer 214.

The first adhesive layer 211, the back plate 220, and the second adhesive layer 212 may be disposed under the display panel 110 to act as a cushion that absorbs an external force while allowing the display panel 110 to maintain the flat surface.

The first adhesive layer 211 is disposed on a rear surface of the display substrate 111. The first adhesive layer 211 contains an adhesive component, and serves to attach the first back plate 221, which is disposed on a bottom surface thereof to allow the display substrate 111 to maintain the flat surface, to the display substrate 111. The first adhesive layer 211 may have a function of protecting the rear surface of the display substrate 111.

The second adhesive layer 212 is disposed on a rear surface of the second back plate 222. The second adhesive layer 212 contains an adhesive component and serves to attach the second back plate 222 disposed on a top surface thereof to the display panel 110. The second adhesive layer 212 may have a function of protecting the rear surface of the display substrate 111.

The third adhesive layer 213 may be disposed on a rear surface of the first back plate 221 to couple the cushion layer 219 to the rear surface of the first back plate 221. The fourth adhesive layer 214 may be disposed on a top surface of the second back plate 222 to couple the cushion layer 219 to the top surface of the second back plate 222.

The first adhesive layer 211, the second adhesive layer 212, the third adhesive layer 213, and the fourth adhesive layer 214 may be double-sided tapes having adhesion. The first adhesive layer 211, the second adhesive layer 212, the third adhesive layer 213, and the fourth adhesive layer 214 may contain an adhesive material, and the adhesive material may be a heat-curing or natural-curing adhesive. The first adhesive layer 211, the second adhesive layer 212, the third adhesive layer 213, and the fourth adhesive layer 214 may be made of a material such as a pressure sensitive adhesive (PSA).

The cushion layer 219 may have adhesive characteristics, and may be formed in a form of a double-sided tape, a foam tape, or a foam pad and formed thicker than the first to fourth adhesive layers 211, 212, 213, and 214 to alleviate the impact on the display panel 110. According to an exemplary embodiment of the present disclosure, the cushion layer 219 may be formed of the same material as the first to fourth adhesive layers 211, 212, 213, and 214. Alternatively, the cushion layer 219 may be formed of a different material from any one the first to fourth adhesive layers 211, 212, 213, and 214, but the present disclosure is not limited thereto.

The protective film 170 is disposed in the partial bezel area BZ with the bent area BA of the display device 100. The protective film 170 may be disposed to overlap the coating layer 158. In the partial bezel area BZ having the bent area BA of the display device 100, the protective film 170 may be disposed in a structure to surround the bent area BA.

The protective film 170 may be disposed to overlap at least a portion of the cover member 20 in the partial bezel area BZ with the bent area BA of the display device 100 and to cover the coating layer 158 and at least a portion of a side surface of an edge of the back plate 220.

The protective film 170 may be disposed as shown in FIG. 4 in one partial bezel area BZ where the bent area BA of the display panel 110 is disposed, and the resin layer 90 may be disposed as shown in FIG. 6 in the remaining three partial bezel areas BZ where the bent area BA is not disposed.

A thickness of the protective film 170 disposed in one partial bezel area BZ with the bent area BA of the display panel 110 may be smaller than a thickness of the resin layer 90 disposed in the remaining three partial bezel areas BZ without the bent area BA.

In this regard, an air gap between the display panel 110 and other components may be minimized and a thin bezel may be implemented by placing the protective film 170, which is thinner than the resin layer 90, in the partial bezel area BZ with the bent area BA where a width and the thickness of the bezel area BZ may relatively increase.

As the protective film 170 has the smaller thickness than the resin layer 90, a space between the display panel 110 or/and the optical plate 180 and the cover member 20 may be completely filled without creating an uncoated area.

Specifically, in the partial bezel area BZ with the bent area BA, the cover member 20 and the coating layer 158 may be disposed to be spaced apart from each other. The protective film 170 may be disposed to overlap at least a portion of a rear surface of the cover member 20 within the space defined as the rear surface of the cover member 20 and a top surface of the coating layer 158 are spaced apart from each other, and may be disposed to overlap an entirety of the top surface of the coating layer 158.

The optical adhesive member 190, which is disposed between the cover member 20 and the display panel 110, and the optical plate 180, which is disposed between the optical adhesive member 190 and the display panel 110 and protrudes further toward the bent area BA than the optical adhesive member 190, may be disposed in the space defined as the cover member 20 and the coating layer 158 are spaced apart from each other. The protective film 170 may be disposed to cover a side surface of the optical adhesive member 190 perpendicular to the top surface of the display panel 110 in the non-display area NA adjacent to the bent area BA, a side surface of the optical plate 180 perpendicular to the top surface of the display panel 110, and a protruding top surface of the optical plate 180.

The protective film 170 may be disposed to cover the light-blocking pattern 22 disposed adjacent to the bent area BA.

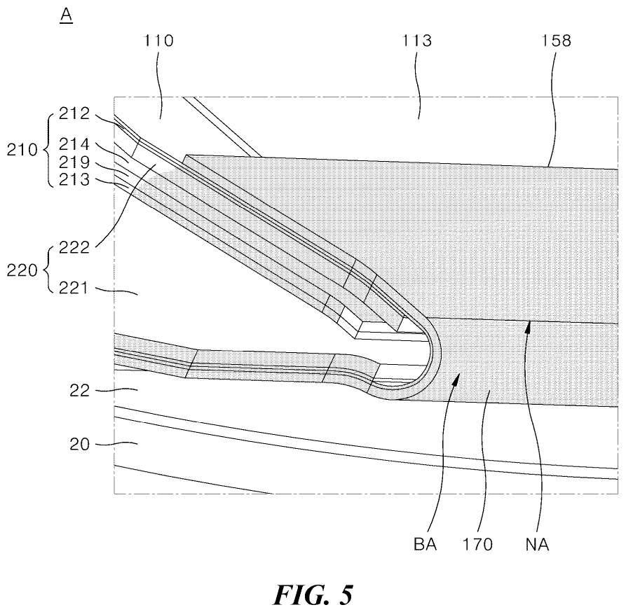

As shown in FIG. 5, the protective film 170 may be disposed to surround a side surface of an edge of the first back plate 221 and a side surface of an edge of the first adhesive layer 211 adjacent to the bent area BA, and a side surface of an edge of the second back plate 222 and a side surface of an edge of the second adhesive layer 212 adjacent to the bent area BA.

The protective film 170 may be disposed to overlap a side surface of an edge and a top surface of the coating layer 158 that is disposed to cover the bent area BA and extends to the non-display area NA adjacent to the bent area BA to overlap at least the portion of back plate 220.

The protective film 170 may be disposed to cover the coating layer 158 and a side surface of an edge of the display panel 110 in the bent area BA, and disposed to cover the coating layer 158, the edge of the display panel 110, and a side surface of at least partial edge of the back plate 220 in the non-display area NA adjacent to the bent area BA.

The protective film 170 may be disposed to cover a side surface of an edge of the cushion layer 219 in the non-display area NA. The protective film 170 may be disposed to at least partially cover a side surface of an edge of the first adhesive layer 211, a side surface of an edge of the second adhesive layer 212, a side surface of an edge of the third adhesive layer 213, and a side surface of an edge of the fourth adhesive layer 214 in the non-display area NA.

The first adhesive layer 211, the second adhesive layer 212, the third adhesive layer 213, and the fourth adhesive layer 214 may be double-sided tapes having adhesion. The first adhesive layer 211, the second adhesive layer 212, the third adhesive layer 213, and the fourth adhesive layer 214 may contain an adhesive material, and the adhesive material may be a heat-curing or natural-curing adhesive. The first adhesive layer 211, the second adhesive layer 212, the third adhesive layer 213, and the fourth adhesive layer 214 may be made of a material such as a pressure sensitive adhesive (PSA).

By placing the protective film 170 on the partial bezel area BZ with the bent area BA, the display device 100 may be prevented from being damaged by the external impact or the like and reliability of the display device 100 may be improved by preventing metal corrosion and blocking gas, moisture, and the like.

The protective film 170 may be made of a material different from that of the resin layer 90. The protective film 170 may be made of a material that is a film containing an organic material but not containing isobornyl acrylate (IBOA). The protective film 170 may contain a parylene-based organic material. As the protective film 170, a parlyne C-based material may be used. Using the parlyne-based material as the protective film 170, the protective film 170 may have a constant thickness in the bezel area BZ and minimize thermal deformation.

The protective film 170 according to an exemplary embodiment of the present disclosure may have excellent gas blocking characteristics, have excellent resistance to a solvent such as acid and alkali, minimize or reduce OUT gassing occurring internally, and have excellent water vapor transmission rate (WVTR). Therefore, the protective film 170 may be disposed in the partial bezel area BZ including the bent area BA where there is a relatively complex arrangement and where driving parts may be disposed closely, thereby improving the reliability of the display device 100.

The protective film 170 is composed of the material that does not contain isobornyl acrylate (IBOA), thereby preventing a harmful effect on a human body and implementing an eco-friendly product.

Referring to FIG. 6, the resin layer 90 may be disposed in the partial bezel area BZ of the display panel 110 where the display panel 110 is not bent. Specifically, the resin layer 90 may be disposed on the three sides of the display panel 110 excluding the one side of the display panel 110 with the bent area BA to surround at least portion of the rear surface of the cover member 20, the side surfaces of the display panel 110, and side surfaces of the back plates 220 and 221, and contain a material different from that of the protective film 170. For example, the protective film 170 may be disposed as shown in FIG. 4 in one side of the display panel 110 where the bent area BA is disposed, and the resin layer 90 may be disposed as shown in FIG. 6 on the three sides of the display panel 110 excluding the one side of the display panel 110 with the bent area BA to surround at least portion of the rear surface of the cover member 20, the side surfaces of the display panel 110, and side surfaces of the back plates 220 and 221, and contain a material different from that of the protective film 170. However, the present disclosure is not limited thereto.

The resin layer 90 may be disposed to be in contact with at least one side surface of the optical adhesive member 190, at least one side surface and at least partial top surface of the optical plate 180, one side surface of the display panel 110 where the bent area BA of the display panel 110 is not disposed, and one side surface of the first back plate 221. The resin layer 90 may be in contact with a rear surface of the light-blocking pattern 22 disposed on the rear surface of the cover member 20.

The resin layer 90 may be disposed to fill the space between the cover member 20 and the protruding top surface of the optical plate 180, which is disposed to protrude further toward the bezel area BZ than the optical adhesive member 190. The resin layer 90 may be disposed to cover the side surface of the optical adhesive member 190 perpendicular to the top surface of the display panel 110, the side surface of the optical plate 180 perpendicular to the top surface of the display panel 110, and the protruding top surface of the optical plate 180 on the three sides or the partial bezel areas BZ of the display panel 110 excluding the bent area BA.

The optical plate 180 is disposed between the display panel 110 and the cover member 20 to further protrude toward the bezel area BZ than the optical adhesive member 190, so that a separation space may be defined between the cover member 20 and the display panel 110 or between the cover member 20 and the optical plate 180. In the present disclosure, the space between the cover member 20 and the display panel 110 or the space between the cover member 20 and the optical plate 180 is covered by the resin layer 90, so that the top surfaces and the side surfaces of the optical plate 180 and the display panel 110 are not exposed to the outside, thereby preventing the foreign substances, the moisture, and air from penetrating into the top and side surfaces of the display panel 110.

The side surfaces where the resin layer 90 described above is disposed may include side surfaces of the remaining three sides of the display panel 110 where the bent area BA of the display panel 110 is not disposed.

As an example, the resin layer 90 may be disposed in the remaining three partial bezel areas BZ of the display panel 110 where the bent area BA of the display panel 110 is not disposed. The resin layer 90 may be disposed to surround the partial bezel areas BZ of the display panel 110 where the protective film 170 in FIG. 4 is not disposed. The resin layer 90 may be disposed to fill a space between the cover member 20 and a bottom member 280 on the side of the display panel 110 or on the bezel area BZ.

The resin layer 90 may be disposed in the bezel area BZ of the display device 100 to prevent the foreign substances, the moisture, and the like from penetrating into the display panel 110, and may attach and fix the display panel 110 to the cover member 20.

The resin layer 90 may attach the cover member 20 and the back plates 220 and 221 to each other between the cover member 20 and the back plates 220 and 221 in the partial bezel areas BZ not including the bent area BA, and the resin layer 90 may attach the adhesive member 210, the back plate 220, and the bottom member 280 to each other at the side of the adhesive member 210 to allow the display panel 110 to be firmly coupled to the cover member 20 or the bottom member 280, thereby improving the rigidity of the display device 100.

The resin layer 90 may be an adhesive member such as glue. The resin layer 90 may be a transparent adhesive member. The resin layer 90 may contain resin. For example, the resin layer 90 may contain ultraviolet (UV) curable acrylic resin or thermosetting resin, but the present disclosure may not be limited thereto.

As such, the protective film 170 is disposed in the partial bezel area BZ of the display device 100 where the bent area BA is disposed to cover a perimeter of one side surface of the display panel 110, and the resin layer 90 is disposed in the remaining partial bezel areas BZ of the display device 100 where the bent area BA is not disposed to cover a perimeter of the display panel 110, so that the air gap between the display panel 110 and other components may be minimized in the partial bezel area BZ with the bent area BA where the width and the thickness of the bezel area BZ may relatively increase, thereby implementing the thin bezel.

When the resin layer 90 is disposed, the resin layer 90 is in a molten state and thus is able to flow into an interface between layers of a display panel assembly. For example, when placing the resin layer 90 in the molten state or bonding the display panel 110 to the cover member 20, some of charges migrating in the display panel 110 may be introduced into to the driving film 113, which is disposed adjacent to the bent area BA, when the protective film 170 is not disposed on the bent area BA according to the present disclosure, which may cause a charge charging defect in the display panel 110, causing a defect such as an edge bright spot (EBS).

The display device 100 according to the present disclosure places the protective film 170 on the partial bezel area BZ (including the bent area BA of the display panel 110) of the display device 100 where the bent area BA of the display panel 110 is disposed to cover a portion adjacent to the bent area BA, thereby preventing the charges from migrating toward the display panel 110 or the driving film 113. Accordingly, the display device 100 according to the present disclosure may reduce the charge charging defect of the display panel 110 and thus improve the reliability of the display device 100.

The display device 100 may further include the bottom member 280 disposed under the back plates 220 and 221, as shown in FIG. 6. The bottom member 280 may be coupled with the cover member 20 via the resin layer 90.

The bottom member 280 accommodates and supports the display panel 110, structures on the top surface of the display panel 110, for example, the optical plate 180 and/or structures on the rear surface of the display panel 110, for example, the back plate 220 and the like. The bottom member 280 may be a heat sink. The bottom member 280 may function to protect the display panel 110 from the outside while supplementing the rigidity of the display panel 110.

Although embodiments of the present disclosure have been described with reference to the accompanying drawings, the present disclosure is not limited to the above embodiments, but may be implemented in various different forms. A person skilled in the art may appreciate that the present disclosure may be practiced in other concrete forms without changing the technical spirit or essential characteristics of the present disclosure. Therefore, it should be appreciated that the embodiments as described above is not restrictive but illustrative in all respects.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a display panel including a display area and a non-display area, the non-display area including a bent area;
a cover member disposed on a front surface of the display panel;
a back plate disposed on a rear surface of the display panel;
a coating layer disposed on the bent area of the non-display area; and
a protective film disposed to overlap at least a portion of the cover member on the bent area and to cover the coating layer and at least a portion of a side surface of an edge of the back plate.

2. The display device of claim 1, wherein the protective film is disposed on one partial bezel area of the display panel corresponding to the bent area, and the display device further comprises:
a resin layer disposed on three remaining partial bezel areas of the display panel excluding the bent area.

3. The display device of claim 2, wherein a thickness of the protective film is less than a thickness of the resin layer.

4. The display device of claim 1, wherein the back plate includes:
a first back plate disposed on the rear surface of the display panel with a first adhesive layer interposed therebetween; and
a second back plate disposed on the rear surface of the display panel with a second adhesive layer interposed therebetween,
wherein the first back plate and the second back plate are disposed to be spaced apart from each other with the bent area interposed therebetween, or are disposed to be spaced apart from each other on the non-display area adjacent to the bent area.

5. The display device of claim 4, wherein the protective film covers a side surface of an edge of the first back plate and a side surface of an edge of the first adhesive layer adjacent to the bent area, and a side surface of an edge of the second back plate and a side surface of an edge of the second adhesive layer adjacent to the bent area.

6. The display device of claim 1, wherein the coating layer is disposed to cover the bent area, extend to the non-display area adjacent to the bent area, and overlap at least a portion of the back plate,
wherein the protective film is disposed to overlap a side surface of an edge of the coating layer and a top surface of the coating layer.

7. The display device of claim 6, wherein the protective film is disposed to cover the coating layer and a side surface of an edge of the display panel on the bent area, and to cover the coating layer, a side surface of an at least partial edge of the display panel, and a side surface of an at least partial edge of the back plate on the non-display area adjacent to the bent area.

8. The display device of claim 1, wherein the back plate includes a first back plate disposed adjacent to the display area of the display panel and a second back plate disposed adjacent to the non-display area of the display panel,
wherein the display device further includes an adhesive member disposed between the display panel and the back plate,
wherein the adhesive member includes a cushion layer disposed between the first back plate and the second back plate,
wherein the protective film is disposed to cover a side surface of an edge of the cushion layer on the non-display area.

9. The display device of claim 8, wherein the adhesive member further includes:
a first adhesive layer disposed between the display panel and the first back plate adjacent to the display area of the display panel;
a second adhesive layer disposed between the display panel and the second back plate adjacent to the non-display area of the display panel; and
a third adhesive layer and a fourth adhesive layer disposed between the first back plate and the second back plate,
wherein the cushion layer is disposed between the third adhesive layer and the fourth adhesive layer,
wherein the protective film is disposed to at least partially cover a side surface of an edge of the first adhesive layer, a side surface of an edge of the second adhesive layer, a side surface of an edge of the third adhesive layer, and a side surface of an edge of the fourth adhesive layer on the non-display area.

10. The display device of claim 1, wherein the cover member and the coating layer are disposed to be spaced apart from each other in a bezel area including the bent area,
wherein the protective film is disposed to overlap at least a portion of a rear surface of the cover member and overlap an entirety of a top surface of the coating layer in a space between the rear surface of the cover member and the top surface of the coating layer.

11. The display device of claim 10, further comprising:
an optical adhesive member disposed between the cover member and the display panel within the space; and
an optical plate disposed between the optical adhesive member and the display panel and protruding further toward the bent area than the optical adhesive member,
wherein the protective film is disposed to cover a side surface of the optical adhesive member that is perpendicular to a top surface of the display panel, a side surface of the optical plate that is perpendicular to the top surface of the display panel, and a protruding top surface of the optical plate in the non-display area adjacent to the bent area.

12. The display device of claim 1, further comprising:
a light-blocking pattern disposed on an edge of a rear surface of the cover member adjacent to the bent area,
wherein the protective film is disposed to cover the light-blocking pattern.

13. The display device of claim 1, wherein the protective film is a film containing a parylene-based organic material and excluding isobornyl acrylate (IBOA).

14. A display device of claim 1, comprising:
a display panel including a display area and a non-display area, the non-display area including a bent area;
a cover member disposed on a front surface of the display panel;
a back plate disposed on a rear surface of the display panel;
a coating layer disposed on the bent area of the non-display area;
a protective film disposed to overlap at least a portion of the cover member on the bent area and to cover the coating layer and at least a portion of a side surface of an edge of the back plate; and
a resin layer surrounding at least a portion of a rear surface of the cover member, a side surface of the display panel, and a side surface of the back plate on three sides of the display panel excluding one side of the display panel having the bent area, and containing a material different from a material of the protective film.

15. The display device of claim 14, further comprising:
an optical adhesive member disposed between the cover member and the display panel; and
an optical plate disposed between the optical adhesive member and the display panel and protruding further toward a bezel area than the optical adhesive member,
wherein the resin layer is disposed to cover a side surface of the optical adhesive member that is perpendicular to the top surface of the display panel, a side surface of the optical plate that is perpendicular to the top surface of the display panel, and a protruding top surface of the optical plate on the three sides of the display panel excluding the bent area.

16. The display device of claim 14, wherein the back plate includes:
a first back plate disposed on the rear surface of the display panel with a first adhesive layer interposed therebetween; and
a second back plate disposed on the rear surface of the display panel with a second adhesive layer interposed therebetween,
wherein the first back plate and the second back plate are disposed to be spaced apart from each other with the bent area interposed therebetween, or are disposed to be spaced apart from each other on the non-display area adjacent to the bent area.

17. A display device, comprising:
a display panel including a display area and a non-display area, the non-display area having a bent area;
a bezel area disposed on four sides of the display panel;
a coating layer disposed on the bent area of the non-display area of the display panel;
a protective film disposed to overlap at least a portion of the coating layer on one partial bezel area in the bezel area corresponding to the bent area; and
a resin layer disposed on three remaining partial bezel areas.

18. The display device of claim 17, wherein a thickness of the protective film is less than a thickness of the resin layer.

19. The display device of claim 17, wherein the protective film has a material different from a material of the resin layer.

20. The display device of claim 17, wherein the protective film contains a parylene-based organic material, and is composed of a material excluding isobornyl acrylate (IBOA).

21. The display device of claim 17, further comprising:
a cover member disposed on a front surface of the display panel and covering the bezel area; and
a back plate disposed on a rear surface of the display panel,
wherein the protective film is disposed to extend along at least a portion of a rear surface of the cover member, a top surface and a side surface of the coating layer, and a side surface of an edge of the back plate.
